(19) United States
(12) Patent Application Publication
(10) Pub. No.: US 2025/0105195 A1
(43) Pub. Date: Mar. 27, 2025

(54) ELECTRONIC COMPONENT PACKAGE HAVING A METAL PLATE STRUCTURE THAT INCLUDES A TAPERED FOOT PORTION

(71) Applicant: TEXAS INSTRUMENTS INCORPORATED, DALLAS, TX (US)

(72) Inventors: JOHN CARLO MOLINA, LIMAY (PH); RAFAEL JOSE LIZARES GUEVARA, Makati Metro Manila (PH)

(21) Appl. No.: 18/474,703

(22) Filed: Sep. 26, 2023

(51) Int. Cl. H01L 23/00; H01L 21/56; H01L 23/31; H01L 23/495

(52) U.S. Cl. CPC H01L 24/29; H01L 21/565; H01L 23/3185; H01L 23/495; H01L 24/27; H01L 2224/27464; H01L 2224/27472; H01L 2224/29011; H01L 2224/29018; H01L 2924/35121

(57) ABSTRACT

One example includes an electronic circuit package. The electronic circuit package includes a lead frame. The electronic circuit package includes an electronic circuit die disposed on the lead frame. The electronic circuit package includes a metal plate structure formed on the electronic circuit die, the metal plate structure comprising an aperture that extends through the metal plate structure from a first surface coupled to the electronic circuit die to a second surface opposite the first surface, and further comprising a tapered foot portion formed around a periphery of the metal plate structure at the first surface. The electronic circuit package includes a molding material covering the electronic circuit die around the metal plate structure.

### TECHNICAL FIELD

The present invention relates generally to electronic component packages, and more particularly to an electronic component package having a metal plate structure that includes a tapered foot portion.

### BACKGROUND

Electronic component packages include electronic components such as an integrated circuit mounted on a substrate. Integrated circuits demand meticulous attention to packaging. Electronic component packages containing integrated circuits are not only expensive and delicate but are susceptible to cracks and delamination. Integrated circuits come in various sizes and shapes that are often irregular, making it challenging to find suitable packaging solutions that can effectively protect them. Electronic packaging relies on engineering principles such as dynamics, stress analysis, heat transfer, and fluid mechanics.

The design of electronic component packages depend on the production method and require careful consideration of dimensions, tolerances, and tooling design. Electronic packaging require engineers to perform analyses to estimate such things as maximum temperatures for components, structural resonant frequencies, and dynamic stresses and deflections under worse-case environments to prevent immediate or premature electronic product failures.

### SUMMARY

The following is a brief summary of the subject matter that is described in greater detail herein. This summary is not intended to be limiting as to the scope of the claims.

In a first example, an electronic component package includes a lead frame. The electronic component package includes an electronic circuit die disposed on the lead frame. The electronic component package includes a metal plate structure formed on the electronic circuit die, the metal plate structure comprising an aperture that extends through the metal plate structure from a first surface coupled to the electronic circuit die to a second surface opposite the first surface, and further comprising a tapered foot portion formed around a periphery of the metal plate structure at the first surface. The electronic component package includes a molding material covering the electronic circuit die around the metal plate structure.

According to a second example, a method of forming an electronic component package includes forming a lead frame. The method of forming an electronic component package includes forming an electronic circuit die on the lead frame. The method of forming an electronic component package includes forming a photoresist layer on the electronic circuit die, the photoresist comprising an aperture that extends through the photoresist layer to a surface of the electronic circuit die and an indentation about a periphery of the aperture. The method of forming an electronic component package includes depositing a metal layer to fill the aperture, the metal layer comprising a tapered foot portion that is contoured to fill the indentation. The method of forming an electronic component package includes removing the photoresist layer. The method of forming an electronic component package includes forming a molding material to cover the electronic circuit die around the metal layer.

According to a third example, a method of forming an electronic component package includes forming a lead frame. The method of forming the electronic component package includes forming an electronic circuit die on the lead frame. The method of forming the electronic component package includes forming a photoresist layer on the electronic circuit die, the photoresist comprising a ring-shaped aperture that extends through the photoresist layer to a surface of the electronic circuit die and a first indentation about an inner periphery of the ring-shaped aperture and a second indentation about an outer periphery of the aperture. The method of forming the electronics component package includes depositing metal material in the aperture to form a metal ring structure, the metal ring structure comprising a first tapered foot portion that is contoured to fill the first indentation and a second tapered foot section that is contoured to fille the second indentation. The method of forming the electronic component package includes removing the photoresist layer. The method of forming the electronic component package includes forming a molding material to cover the electronic circuit die around the outer periphery of the ring structure.

### BRIEF SUMMARY OF THE DRAWINGS

The general inventive concepts, as well as illustrative examples and advantages thereof, are described below in greater detail, by way of example, with reference to the drawings in which:

FIG. 1 illustrates a diagram of an electronic component package.

FIG. 2A illustrates a plan view of an electronic component package.

FIG. 2B illustrates a cross-section view of an electronic component package.

FIG. 3 illustrates an explanatory diagram showing an example of lithography used in the fabrication process of the electronic component package.

FIG. 4 illustrates a top view of a fabricated electronic component package.

FIG. 5 illustrates an example of a flow diagram for forming an electronic component package.

### DETAILED DESCRIPTION

The present disclosure describes an electronic component package and a method of forming a metal ring structure therein having a tapered foot portion that is contoured to an indentation in the chip molding. As described herein, the tapered foot portion is of particular significance with respect to the prevention of stress fractures and cracks from occurring in the active circuitry and silicon substrate of the electronic component package. As described herein, the formation of the tapered foot portion of the metal ring structure provides improvements in the support against high stress concentration points.

As an example, the electronic component package described herein includes a metal plate structure comprising a central aperture for sensing dampness, moisture, and humidity in the operating environment. In one example, the walls of the central aperture can be plated with metal to form the metal ring structure. As an example, one or more tapered foot portions of the metal ring structure can be formed along the surface of the electronic circuit die. The formation of the metal ring structure having the one or more tapered foot portions improves the adhesion of the mold compound to the metal ring structure and the electronic circuit die of the electronic component package, thereby mitigating the formation of cracks in the electronic circuit die resulting from mechanical stress.

The process of forming the metal ring structure having the tapered foot portion, as described herein, includes forming a photoresist coat layer on the electronic circuit die. The photoresist coat layer can be provided with an aperture extending through the photoresist coat layer to the top surface of the electronic circuit die. A soft bake can be performed on the photoresist coat layer at approximately 130° C. or less. An exposure process can be performed at least approximately 1900 mJ/cm². A post-exposure bake can then be performed on the photoresist coat layer at greater than approximately 100° C. A puddle development process can be performed greater than 9 iterations to form the tapered foot portion of the metal ring structure.

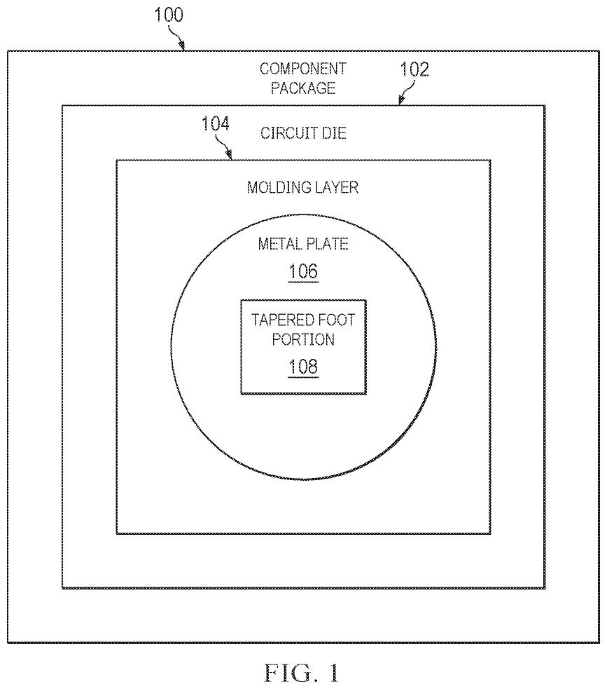

Referring to FIG. 1, a block diagram of an electronic circuit package 100 in accordance with the disclosure is depicted. The electronic circuit package 100 includes a circuit die 102, a molding layer 104, a metal plate structure 106, and one or more tapered foot portions 108 of the metal plate structure 106. For example, the metal plate structure 106 can be formed in a loop that includes an aperture extending through the metal plate structure to a surface of the circuit die 102. As an example, the electronic circuit package 100 of the present disclosure can be configured to sense an atmospheric environment in the aperture of the metal plate structure 106, such as to detect properties of the relative humidity of air or gas (e.g., temperature, pressure, mass, etc.) as moisture is absorbed in the operating environment of the electronic circuit package 100.

The circuit die 102 can be provided on the surface of a lead frame (not shown). The metal plate structure 106 can be configured on a central portion of the circuit die 102. The molding layer 104 can be formed around the outer periphery of the metal plate structure 106. The molding layer 104 can be configured to extend from the surface of the circuit die 102 to the upper portion of the metal plate structure 106. The molding layer 104 can be configured to cover the entire surface of the circuit die 102.

In one example, the metal plate structure 106 can be configured to comprise one or more tapered foot portions 108 along the surface of the circuit die 102. The metal plate structure 106 can also be configured to have a trapezoidal sloped interior wall to relieve stress points of the electronic circuit package 100 from forming at a material junction therein. The metal plate structure 106 comprising the one or more tapered foot portions 108 can allow for increased support for material reliability. Also, to form the tapered foot portion 108, a photoresist material layer (not shown) can be formed to provide an indentation along the surface of the circuit die 102. The tapered foot portion 108 of the metal plate structure 106 can thus be formed to fill the indentation at the junction where the molding layer 104 and the circuit die 102 meets.

For example, outside of the metal plate structure 106, the molding layer 104 surrounds the periphery of the metal plate structure 106. A first tapered foot portion 108 can be formed around the lower outer periphery of the metal plate structure 106 to fill the indentation formed in a lower portion of the photoresist material layer. The photoresist material layer above the indentation can be configured as an angled wall. The sloping configuration of the indentation allows for additional relief at the stress points in the circuit die 102 when filled with a metal material to form the tapered foot portion 108 of the metal plate structure 106. The inner periphery of the metal plate structure 106 can be configured to comprise a second tapered foot portion 108 along the surface of the circuit die 102 for additional structural support.

As described above, the metal plate structure 106 can be formed as a loop (e.g., a circular ring), such that the metal plate structure 106 includes an aperture (not shown) to draw in air or other gas for sensing. The aperture can be configured to sense the temperature of condensation (e.g., a dew point) near or around the electronic circuit package 100. The metal plate structure 106, adjacent to the molding layer 104, forms an opening of the aperture. The aperture can be configured to extend down to the surface of the circuit die 102 to allow sensing of atmospheric sensing within the aperture.

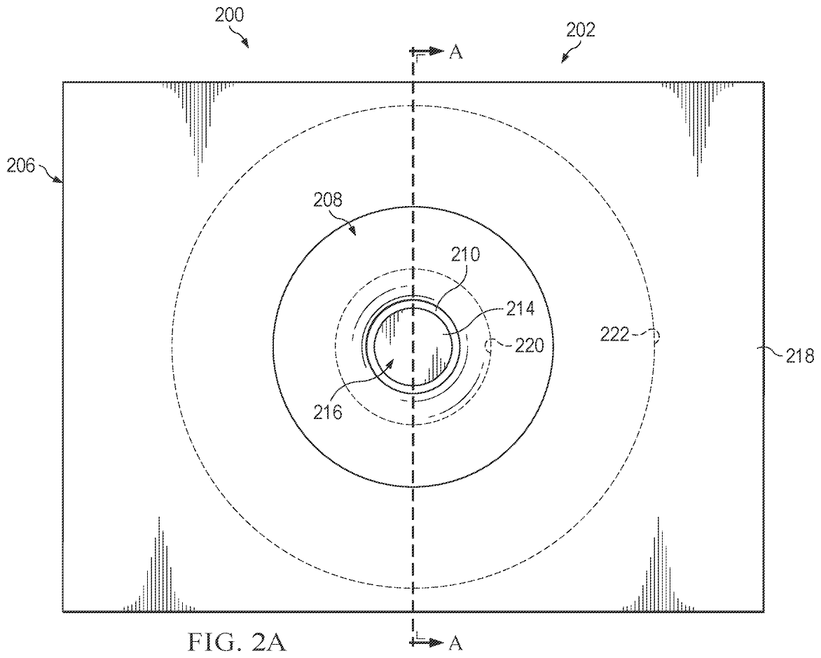

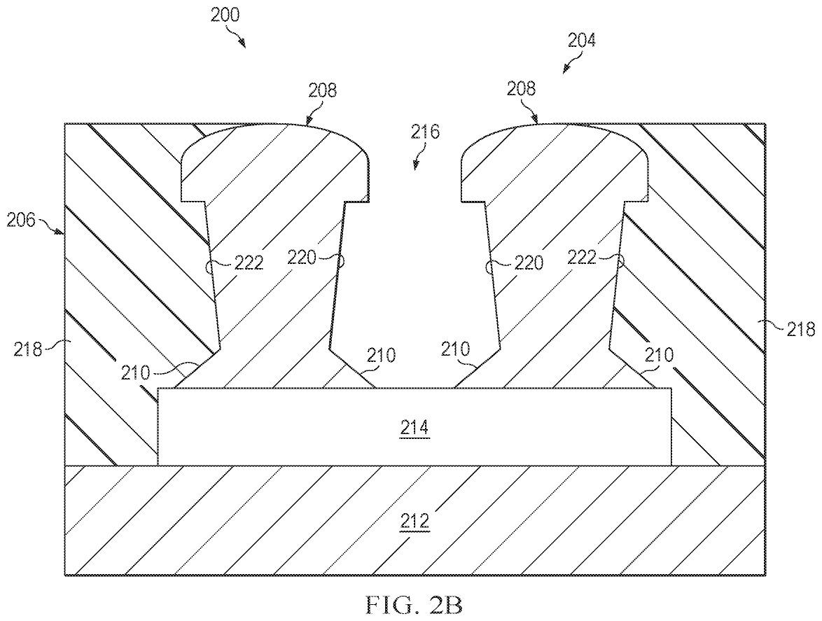

Turning now to FIGS. 2A and 2B, a diagram 200 of an electronic circuit package having an aperture including a metal ring comprising a tapered foot portion is shown. The diagram 200 includes a first view 202 that is a plan view of a surface of the electronic circuit package, hereinafter electronic circuit package 206, comprising a metal plate structure 208. The diagram also includes a second view 204 that is a cross-sectional view of the electronic circuit package 206 through “A” comprising the metal plate structure 208 that includes a tapered foot portion 210 on both the interior and exterior peripheries of the metal plate structure 208. The electronic circuit package 206 is depicted in the example of FIGS. 2A and 2B as a simplistic example for brevity and ease of description.

The electronic circuit package 206 can be formed on a lead frame 212 which can provide mechanical support and electrical connections for the circuit die 214. The lead frame 212 can be used in a variety of die configurations (e.g., DIP, QFP and other packages) to provide electrical connections to the electronic circuit package 206. The lead frame 212 includes a central die pad (not shown), where the circuit die 214 is placed, surrounded by leads (not shown) or conductive paths that can lead to other circuit components. The circuit die 214 is glued or soldered to the central die pad inside the lead frame. Bond wires (not shown) can be attached between the central die pad and a set of bond pads (not shown) to connect the central die pad to the leads.

In one example, the metal plate structure 208 can be plated via a electroless deposition process through which metals and metal alloys are deposited onto the circuit die 214 when an external current is applied. A mushroom-shaped cross-section can be formed on the metal plate structure 208 to provide partial cover over the circuit die 214. The metal plate structure 208 includes an aperture 216 that extends to the electronic circuit package 206 through which air and gas can be sensed by sensors (not shown) in the circuit die.

The metal plate structure 208 can be configured to comprise one or more tapered foot portions 210 to relieve stress points that form from the fabrication of the electronic circuit package 206. A molding layer 218 can be formed around the metal plate structure 208 encasing the electronic circuit package 206. Junctions between the molding layer 218, the metal plate structure 208, and the circuit die 214 are relieved from cracking and delamination by the angled support of the tapered foot portion 210. The tapered foot portion 210 can extend between approximately 15% and approximately 25% of the inner radius of the aperture 216 towards the center of the aperture 216 from the base of the metal plate structure 208.

The metal plate structure 208 comprises a first side wall 220 facing the aperture 216 that can be configured to lean inward at an angle towards the center of the aperture 216. The first side wall 220 can be exposed to atmosphere to guide air or gas to the circuit die 214. The metal plate structure 208 comprises a second side wall 222 facing the molding layer 218 than can be configured to lean outward at an angle towards the edges of the electronic circuit package 206. The second side wall 222 meets the tapered foot portion 210 at angle to relieve the stress point and to support the adhesion of the materials. The tapered foot portion 210 prevents the side walls (220, 222) from contacting the circuit die at an angle that would otherwise be prone to cracking in the circuit die 214.

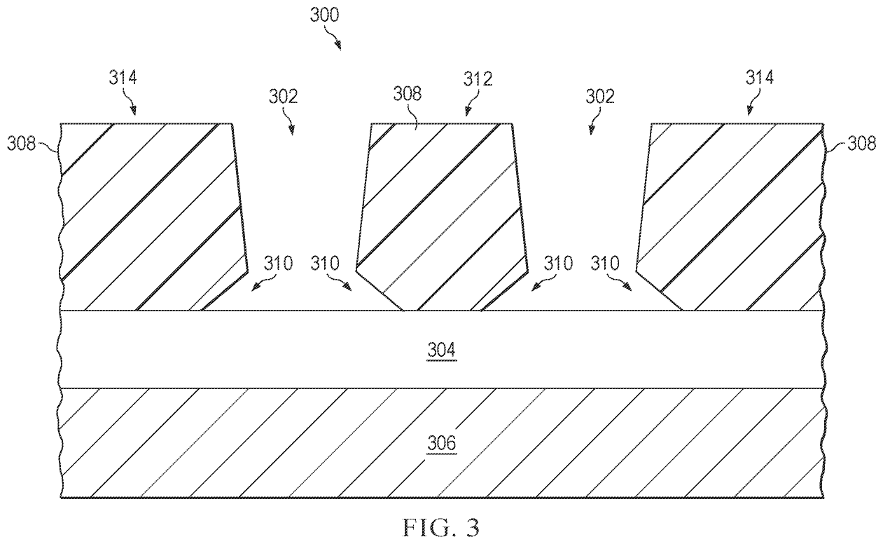

Turning now to FIG. 3, an explanatory diagram of a die assembly 300 is depicted showing an example of lithography used in the fabrication process of the electronic component package. The die assembly 300 is demonstrated in the example of FIG. 3 in a cross-section, such as through “A” in the example of FIG. 2A. The die assembly 300 can be configured to undergo a lithography process to form the metal plate structure of the electronic circuit package including the tapered foot portion as described herein. A metal plate structure profile 302 can be formed on the circuit die 304 and lead frame 306 by depositing a photoresist material 308 on the circuit die 304. In the example of FIG. 3, the metal plate structure profile 302 is demonstrated as including two cavity portions that can collectively correspond to a single loop-shaped cavity. The metal plate structure profile 302 can be filled with a metal (e.g., copper) to form the resultant metal plate structure (e.g., the metal plate structure 208). The photoresist material 308 can be formed to include at least one indentation 310 at the surface of the circuit die 304 that is subsequently filled by metal material to become the tapered foot portion of the metal plate structure.

In one example, a photoresist deposition step can be performed to deposit the photoresist material 308 over the circuit die 304. The photoresist material 308 can be formed over the circuit die 304 having a first portion 312 of the photoresist material 308 and a second portion 314 of the photoresist material 308, such that the loop-shaped cavity of the metal plate structure profile 302 occupies the volume therebetween. The combination of the first portion 312 and the second portion 314 therefore defines the metal plate structure profile 302 to be filled with metal material to form the metal plate structure of the electronic circuit package. In another example, the photoresist material can be formed in one solid layer having the first portion 312 and the second portion 314 of the photoresist material formed during the development process of the metal plate structure. The photoresist material 308 can be applied by a spin coating method that consists of dispensing the photoresist material 308 over the circuit die assembly 300 and rapidly spinning the circuit assembly 300 until it becomes dry. Alternatively, the photoresist material 308 could be applied by a laser printer.

A soft bake process is performed on the photoresist material 308 to evaporate solvents within the photoresist material 308 to make the formation more solid for filling the metal plate structure profile 302 during the metal plate structure development process. The soft bake process also improves the adhesion of the photoresist material 308 to the circuit die 304. The soft bake process is performed at approximately 130° C. or less (e.g., at approximately 125° C.), which can be less than a soft bake process for a photolithography process for conventional chip fabrication (e.g., typically approximately 140° C.). The evaporation of solvents within the photoresist material 308 can change the thickness of the photoresist material 308 so that it can be prepared for exposure to ultraviolet light during the exposure process.

The exposure process can be performed on the circuit die assembly 300 after the soft bake. The exposure process can be performed by exposing the photoresist material 308 of the circuit die assembly 300 to ultraviolet light at a rate of at least approximately 1900 mJ/cm² (e.g., approximately 2000 mJ/cm²). The exposure process can be performed to produce radiation to form the pattern image on the photoresist material 308 which defines what will become the metal plate structure profile 302 during the development step. The exposure process performed on the circuit die assembly 300 can be greater than an exposure process for conventional chip fabrication (e.g., typically approximately 1800 mJ/cm²). The pattern can be formed on the circuit die assembly 300 using a mask which defines the area of the photoresist material surface to be exposed to radiation and those to be covered. The portions of the photoresist material 308 that are radiated become more soluble during the development process.

In an example, a post-exposure bake can be performed on the circuit die assembly 300 following the exposure step. The post-exposure bake can be performed at greater than approximately 100° C. (e.g., at 105° C.) which drives diffusion of the photoproducts in the photoresist material 308. The diffusion can be useful in minimizing the effects of standing waves from periodic variations in exposure dose throughout the depth of the photoresist material 308 that result from interference of incident and reflected radiation. The post-exposure bake also drive the acid-catalyzed reaction that alters the solubility of the polymer in the photoresist material 308. The post-exposure bake process performed on the circuit die assembly 300 can be greater than an post-exposure bake process for conventional chip fabrication (e.g., typically approximately 100° C.).

A development process can be performed on the circuit die assembly 300 (e.g., puddling). A solvent can be applied to the photoresist material 308 in the pattern defined during the exposure step. Unwanted photoresist material is digested and washed away. The puddle process is performed repetitively to reach a desired depth in the photoresist material 308. A first set of puddling steps can be performed to form a canal down to the circuit die 304 representative of the metal plate structure. The first set of puddling steps can be performed in less than nine iterations (e.g., eight iterations). In a conventional chip fabrication process, the photoresist lithography typically only implements a first set of puddling steps of eight or fewer iterations. However, for fabrication of the circuit die assembly 300, a second set of puddling steps can be performed to form the indentation 310 to be filled by metal to become the tapered foot portion of the metal plate structure. The second set of puddling steps can be performed as including at least two additional iterations (e.g., three additional iterations). By performing the puddling steps approximately eleven iterations the metal plate structure profile 302 can be formed as described herein.

By providing variations of the photolithography process with respect to the soft bake, the expose, the post-exposure bake, and the develop steps relative to conventional fabrication, the photolithography process can be implemented to form the indentation in the metal plate structure profile 302 that allows the formation of the tapered foot portion of the metal plate structure. After the metal plate structure profile 302 has been formed from the development of the photoresist material 308, the metal plate structure profile 302 can be filled by a metal plating process. The metal plating process forms the metal plate structure of the electronic circuit package. The metal plate structure thus includes the tapered foot portion along the surface of the circuit die so that material stress can be resolved due to mitigating right angle adhesion points between the metal plate structure and the circuit die 304. The metal plating process can form overplating, such as a mushroom-shaped cap along the top surface of the metal plate structure, for mold bleed control when the molding layer is applied to the circuit die assembly 300 later in the electronic circuit package assembly process.

After the metal plate structure has been formed, the remaining photoresist material 308 can be removed from the circuit die assembly 300. Once the photoresist material has been removed, a chemical roughening process can be performed on the tapered foot portion of the metal plate structure. The chemical roughening process can form grooves in the tapered foot portion for improved adhesion to the molding material of the electronic circuit package. The grooved tapered foot portion of the metal plate structure provides for a more durable electronic circuit package.

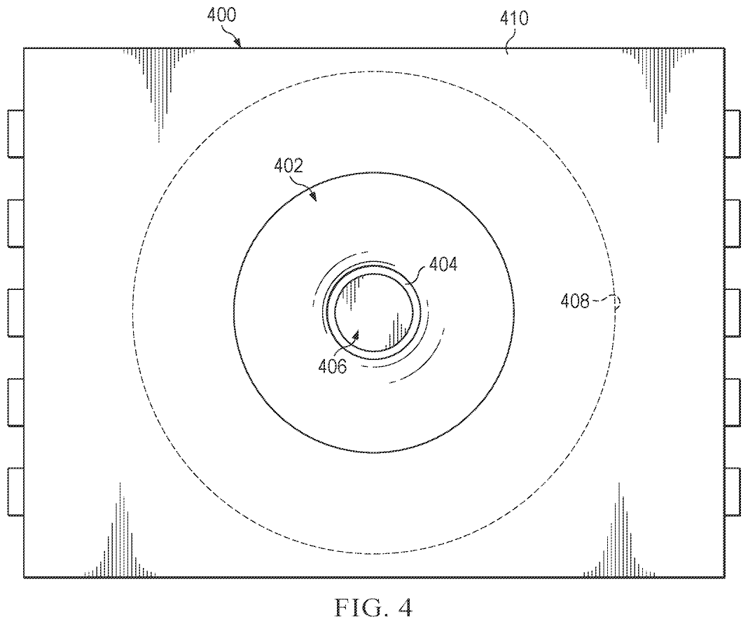

Turning now to FIG. 4, a fabricated electronic component packaged is shown. The electronic circuit package 400 described herein is a chip on which a humidity sensor package is formed. The electronic circuit package 400 includes a metal plate structure 402 that is demonstrated as having a looped-shape (e.g., a circular ring). The metal plate structure 402 includes a first tapered foot portion 404 that is provided around an inner-periphery of the metal plate structure 402, and thus circumscribes an aperture 406 that extends through the metal plate structure 402 to a surface of a circuit die of the electronic circuit package 400. The metal plate structure 402 also includes a second tapered foot portion 408 that is provided around an outer-periphery of the metal plate structure 402 and which is occluded in the example of FIG. 4 by a molding material 410.

The molding material 410 can be formed on the circuit die around the outer-periphery of the metal plate structure 402. The molding material 410 can include a molding compound, a molding underfill, an epoxy, or a resin. After the molding process, the top surface of the molding material 410 can be higher than a top surface of the metal plate structure 402. The molding material 410 can be dispensed as a fluid and is then cured to form the electronic component package 400 as depicted in FIG. 4. As described herein, the presence of the first tapered foot portion 404 and/or the second tapered foot portion 408 can mitigate cracks that can form in the circuit die during the application of the molding material 410.

The foregoing outlines features of several examples so that that those skilled in the art may better understand the aspects of the present disclosure. Those skilled in the art should appreciate that they may readily use the present disclosure as a basis for designing or modifying other processes and structures for carrying out the same purposes and/or achieving the same advantages of the examples introduced herein. Those skilled in the art should also realize that such equivalent constructions do not depart from the spirit and scope of the present disclosure, and that they may make various changes, substitutions, alterations herein without departing from the spirit and scope of the present disclosure.

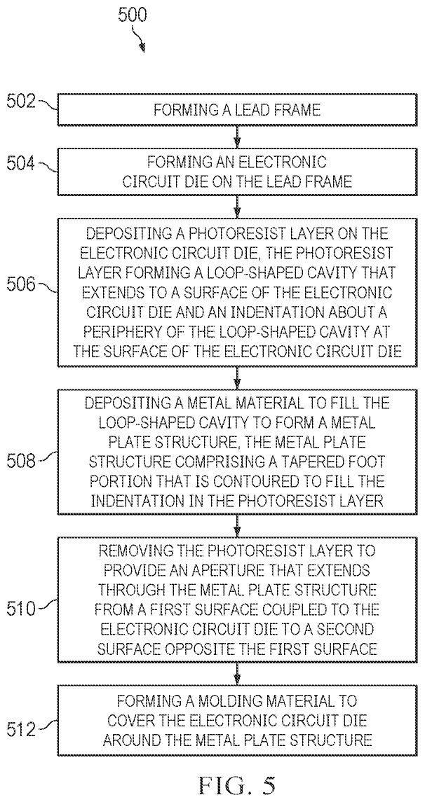

Referring now to the example of FIG. 5, illustrated is a flow diagram 500 for forming an electronic component package in accordance with one or more examples described herein.

At 502, the flow diagram comprises forming a lead frame.

At 504, the flow diagram comprises forming an electronic circuit die on the lead frame.

At 506, the flow diagram comprises depositing a photoresist layer on the electronic circuit die, the photoresist comprising an aperture that extends through the photoresist layer to a surface of the electronic circuit die and in indentation about a periphery of the aperture.

At 508, the flow diagram comprises depositing a metal layer to fill the aperture, the metal layer comprising a tapered foot portion that is contoured to fill the indentation. At 510, the flow diagram comprises removing the photoresist layer.

At 512, the flow diagram comprises forming a molding material to cover the electronic circuit die around the metal layer.

The forming a photoresist layer on the electronic circuit die further includes applying a photoresist material to the electronic circuit die via a spin coating process.

The forming a photoresist layer on the electronic circuit die further includes performing a soft bake process at approximately 130° C. or less.

The forming a photoresist layer on the electronic circuit die further includes exposing the photoresist layer to ultraviolet light at a rate of at least approximately 1900 mJ/cm².

The forming a photoresist layer on the electronic circuit die further includes performing a post bake process at greater than approximately 100° C.

The depositing the metal layer to fill the aperture includes depositing a metal material in each of a first set of nine or fewer puddling procedures to form a first portion of the metal layer and depositing the metal material in each of a second set of at least two puddling procedures to form the tapered foot portions of the metal layer.

The foregoing detailed description is merely illustrative and is not intended to limit examples and/or application or uses of examples. Furthermore, there is no intention to be bound by any expressed or implied information presented in the preceding Background or Summary sections, or in the Detailed Description section.

As used in the specification and the appended claims, the singular forms “a,” “an,” and “the” are intended to include the plural forms as well, unless the context clearly indicates otherwise.

Unless otherwise indicated, any element, property, feature, or combination of elements, properties, and features, may be used in any example disclosed herein, regardless of whether the element, property, feature, or combination was explicitly disclosed in the example. It will be readily understood that features described in relation to any particular aspect described herein may be applicable to other aspects described herein provided the features are compatible with that aspect. In particular, features described herein in relation to the method may be applicable to the optical data transfer product and vice versa.

Reference throughout this specification to “one example,” or “an example,” means that a particular feature, structure, or characteristic described in connection with the example is included in at least one example. Thus, the appearances of the phrase “in one example,” “in one aspect,” or “in an example,” in various places throughout this specification are not necessarily all referring to the same example. Furthermore, the particular features, structures, or characteristics may be combined in any suitable manner in one or more examples.

The words “exemplary” and/or “demonstrative” are used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive—in a manner similar to the term “comprising” as an open transition word—without precluding any additional or other elements.

The above description includes non-limiting aspects of the various examples. It is, of course, not possible to describe every conceivable combination of components or methods for purposes of describing the disclosed subject matter, and one skilled in the art may recognize that further combinations and permutations of various examples are possible. The disclosed subject matter is intended to embrace all such alterations, modifications, and variations that fall within the spirit of the appended claims.

With regard to the various functions performed by the above described components, the terms (including a reference to a “means”) used to describe such components are intended to also include, unless otherwise indicated, any structure(s) which performs the specified function of the described component (e.g., functional equivalent), even if not structurally equivalent to the disclosed structure. In addition, while a particular feature of the disclosed subject matter may have been disclosed with respect to only one of several implementations, such feature may be combined with one or more features of the other implementations as may be desired and advantageous for any given or particular applications.

The terms “exemplary” and/or “demonstrative” as used herein are intended to mean serving as an example, instance, or illustrative. For the avoidance of doubt, the subject matter disclosed herein is not limited to such examples. In addition, any aspect or design described herein as “exemplary” and/or “demonstrative” is not necessarily to be construed as preferred or advantageous over the other aspects or designs, nor is it meant to preclude equivalent structures and techniques known to one skilled in the art. Furthermore, to the extent that the terms “includes,” “has,” “contains,” and other similar words are used in either the detailed description or the claims, such terms are intended to be inclusive—in a manner similar to the term “comprising” as an open transition word—without precluding any additional or other elements.

What is claimed is:

1. An electronic component package comprising:
a lead frame;
an electronic circuit die disposed on the lead frame;
a metal plate structure formed on the electronic circuit die, the metal plate structure comprising an aperture that extends through the metal plate structure from a first surface coupled to the electronic circuit die to a second surface opposite the first surface, and further comprising a tapered foot portion formed around a periphery of the metal plate structure at the first surface; and
a molding material covering the electronic circuit die around the metal plate structure.

2. The electronic component package of claim 1, wherein the electronic circuit die comprises a sensor configured to sense an atmospheric environment in the aperture of the metal plate structure.

3. The electronic component package of claim 1, wherein a surface of the tapered foot portion that is in contact with the molding material comprises a set of grooves for improved adhesion to the molding material.

4. The electronic component package of claim 1, wherein the periphery is an outer periphery external to the aperture, wherein the metal plate structure comprises a first tapered foot portion formed around the inner periphery of the metal plate structure at the first surface and a second tapered foot portion formed around an inner periphery of the metal plate structure about the aperture.

5. The electronic component package of claim 4, wherein the second tapered foot portion extends between approximately 15% and approximately 25% of the radius towards a center of the aperture.

6. The electronic component package of claim 1, wherein the second surface of the metal plate structure comprises overplating for bleed control of the molding material.

7. A method of forming an electronic component package, the method comprising:
forming a lead frame:
forming an electronic circuit die on the lead frame;
depositing a photoresist layer on the electronic circuit die, the photoresist layer forming a loop-shaped cavity that extends to a surface of the electronic circuit die and an indentation about a periphery of the loop-shaped cavity at the surface of the electronic circuit die;
depositing a metal material to fill the loop-shaped cavity to form a metal plate structure, the metal plate structure comprising a tapered foot portion that is contoured to fill the indentation in the photoresist layer;
removing the photoresist layer to provide an aperture that extends through the metal plate structure from a first surface coupled to the electronic circuit die to a second surface opposite the first surface; and
forming a molding material to cover the electronic circuit die around the metal plate structure.

8. The method of claim 7, wherein the depositing the photoresist layer on the electronic circuit die comprises applying a photoresist material to the electronic circuit die via a spin coating process.

9. The method of claim 7, wherein the forming the photoresist layer on the electronic circuit die comprises performing a soft bake process at approximately 130° C. or less.

10. The method of claim 7, wherein the forming the photoresist layer on the electronic circuit die comprises exposing the photoresist layer to ultraviolet light at a rate of at least approximately 1900 mJ/cm².

11. The method of claim 7, wherein the forming the photoresist layer on the electronic circuit die comprises performing a post bake process at greater than approximately 100° C.

12. The method of claim 7, wherein depositing the metal layer to fill the aperture comprises depositing a metal material in each of a first set of nine or fewer puddling procedures to form a first portion of the metal layer and depositing the metal material in each of a second set of at least two puddling procedures to form the tapered foot portions of the metal layer.

13. The method of claim 7, wherein depositing the photoresist layer comprises forming grooves in the indentation, wherein depositing the metal layer comprises depositing the metal layer to fill the grooves of the indentation.

14. The method of claim 7, wherein depositing the photoresist comprises forming the indentation between approximately 15% and approximately 25% of an inner radius of the aperture of the metal plate structure.

15. A method of forming an electronic component package, the method comprising:
forming a lead frame;
forming an electronic circuit die on the lead frame;
forming a photoresist layer on the electronic circuit die, the photoresist comprising a ring-shaped cavity that extends through the photoresist layer to a surface of the electronic circuit die and a first indentation about an inner periphery of the ring-shaped cavity and a second indentation about an outer periphery of the aperture;
depositing metal material in the ring-shaped cavity to form a metal ring structure, the metal ring structure comprising a first tapered foot portion that is contoured to fill the first indentation and a second tapered foot section that is contoured to fill the second indentation;
removing the photoresist layer; and
forming a molding material to cover the electronic circuit die around the outer periphery of the ring structure.

16. The method of claim 15, wherein the depositing the photoresist layer on the electronic circuit die comprises applying a photoresist material to the electronic circuit die via a spin coating process.

17. The method of claim 15, wherein the forming the photoresist layer on the electronic circuit die comprises performing a soft bake process at approximately 130° C. or less.

18. The method of claim 15, wherein the forming the photoresist layer on the electronic circuit die comprises exposing the photoresist layer to ultraviolet light at a rate of at least approximately 1900 mJ/cm².

19. The method of claim 15, wherein the forming the photoresist layer on the electronic circuit die comprises performing a post bake process at greater than approximately 100°.

20. The method of claim 15, wherein depositing the metal layer to fill the ring-shaped cavity comprises depositing a metal material in each of a first set of nine or fewer puddling procedures to form a first portion of the metal layer and depositing the metal material in each of a second set of at least two puddling procedures to form the tapered foot portions of the metal layer.
